(19) United States
(12) Patent Application Publication
(10) Pub. No.: US 2026/0208084 A1
(43) Pub. Date: Jul. 23, 2026

(54) Collection Device that Changes Width of Flow Path According to Pressure

(71) Applicants: Jong-Soo Shin, Cheongju-si, Chungcheongbuk-do (KR); Shinyang Inc., Cheongju-si, Chungcheongbuk-do (KR)

(72) Inventor: Jong-Soo Shin, Cheongju-si, Chungcheongbuk-do (KR)

(21) Appl. No.: 19/141,165

(22) PCT Filed: Oct. 5, 2023
(86) PCT No.: PCT/KR2023/015324

§ 371 Date: Jun. 19, 2025

(30) Foreign Application Priority Data
Dec. 23, 2022 (KR) 10-2022-0183408

(51) Int. Cl. B01D 45/08; B01D 47/10

(52) U.S. Cl. CPC B01D 45/08; B01D 47/10

(57) ABSTRACT

changes the width of a flow path according to pressure and, more specifically, to a collection device that allows the width of a flow path to change according to pressure, by having a partition that can rotate in a way that enables changes in the width of a flow path, so that the tilt angle of a plate part rotating about a rotation part is adjusted according to the pressure of an internal space.

### TECHNICAL FIELD

The present invention relates to a collection device that changes the width of a flow path according to pressure and, more specifically, to a collection device that allows the width of a flow path to change according to pressure, by having a partition that can rotate in a way that enables changes in the width of a flow path, so that the tilt angle of a plate part rotating about a rotation part is adjusted according to the pressure of an internal space.

### Background Art

Generally, semiconductors are manufactured through various processes such as Oxidation, Etching, Deposition, Photolithography, etc., and toxic gases such as ammonia (NH₃), nitric oxide (NO), arsine (AsH₃), phosphine (PH₃), etc., are used in these manufacturing processes.

If waste gas generated in semiconductor manufacturing process is released into atmosphere as it is, aforementioned toxic gases can have fatal adverse effect on human body, and fire accidents due to spontaneous combustion of waste gas can also occur.

For such reason, in semiconductor manufacturing process, generated waste gas is purified through scrubber, etc., and then released into atmosphere.

Such scrubbers comprise a Heat-Wet Scrubber, which is indirect combustion wet type that uses induction heating method to burn waste gas and then filters it once more using water, a Wet Scrubber, which is a wet type that collects waste gas using water and then purifies water, and a Burn-Wet Scrubber, which is direct combustion wet type that burns waste gas with high-temperature flame and then collects it using water.

Regardless of type, scrubbers use water in process of treating waste gas. Since used water contains many pollutants, water containing pollutants must be treated with filter, etc., and discharged to outside through drain pipe.

At this time, if part of the water used in process of treating waste gas of the scrubber is not discharged through drain pipe but is discharged to outside together with purified fluid in liquid or gaseous state, corrosive liquid component may be present in discharged fluid, thereby corroding piping, reducing purification effect of waste gas, and causing fire due to ignition.

Therefore, conventionally, liquid collection device for removing corrosive liquid components from fluid purified in the scrubber has been installed and operated.

FIG. 1 is a diagram illustrating conventional liquid collection device 90, which is disclosed in Korean Patent Publication No. 10-2003-0052170 (Jun. 26, 2003).

Referring to FIG. 1, the conventional liquid collection device 90 is installed on connecting pipe between scrubber S that neutralizes discharged waste gas and exhaust duct D that discharges purified gas through the scrubber S.

The liquid collection device 90 is composed of upper collection container 91 of cylindrical shape and lower collection container 93, and inlet pipe 911 is installed on one side connected on connecting pipe in the upper collection container 91, and exhaust pipe 913 is installed at a height difference on other side opposite to the inlet pipe 911.

Collection net 9131 made of metal is formed inside inlet of the exhaust pipe 913, and discharge port 931 is formed at lower end of the lower collection container 93 to periodically discharge collected powder and condensed water, and cap 9311, which is screw-fastened and sealed, is configured at lower end of the discharge port 931.

And fixing plate 915 of integrally formed disk is configured at lower end of the upper collection container 91, and fixing plate 933 of same size as the fixing plate 915 is formed at upper end of the lower collection container 93, so that the upper collection container 91 and the lower collection container 93 can be brought into contact and bolted.

Gas introduced through inlet pipe 911 of the liquid collection device 90 is filtered and collected by the net 9131, and some powder falls into the lower collection container 93 or adheres to inside of the liquid collection device 90, and in the lower collection container 93, not only powder but also condensed water due to waste gas is collected, and powder and condensed water thus collected in the lower collection container 93 are periodically discharged by unscrewing the cap 9311 which is screw-coupled to the discharge port 931.

However, such conventional liquid collection device 90 has problem in that it cannot block flames when unexpected explosion of scrubber S occurs.

Since waste gas handled in scrubber S comprises combustible gas, ignition due to various causes can occur, leading to fire accidents.

Although sprinkler is installed on exhaust duct D side, so that some fire suppression can be achieved in case of fire, pipe connecting scrubber S and exhaust duct D is made of PVC material to prevent internal corrosion and is vulnerable to fire, therefore, in case of fire accident, flames easily spread along piping, leading to large fire.

Consequently, when explosion of scrubber S occurs during process of treating waste gas, flames will move along piping, and since aforementioned conventional liquid collection device 90 does not have separate configuration for fire prevention and blocking, the liquid collection device 90 also cannot block flames and burns, resulting in serious property damage and casualties.

FIG. 2 is a diagram illustrating installed state of conventional liquid collection device 90, and referring to FIG. 2, in conventional liquid collection device 90, liquid collection was possible only by moving fluid in horizontal direction from one side to other side, and therefore, pipe vertically connected from scrubber S was connected to horizontal pipe, and this horizontal pipe was connected to liquid collection device 90, and exhausted fluid was drawn out through horizontal pipe, then reconnected to vertical pipe and sent to exhaust duct.

That is, according to conventional horizontal liquid collection device 90, considerable amount of space and materials were required to install liquid collection device 90, and after installation, piping became very complicated, making maintenance difficult, and above all, large load was applied inside pipe, and large pressure drop occurred, causing corrosive liquid components contained in fluid to adhere inside pipe, leading to easy corrosion of interior of pipe. In addition, since liquid collection efficiency was low, corrosive liquid components contained in fluid could not be effectively removed.

Accordingly, there is demand in related industry for introduction of new technology that can block spread of fire in case of fire caused by scrubber explosion, minimize space required for installation, prevent waste of materials, facilitate maintenance, prevent corrosion of piping, and increase collection efficiency of corrosive liquid components.
(Patent Publication 1) Korean Patent Publication No. 10-2003-0052170 (Jun. 26, 2003)

### DISCLOSURE

### Technical Problem

Accordingly, the present disclosure has been made keeping in mind the above problems occurring in the related art.

An object of the present disclosure is to provide a collection device that promotes generation of fluid vortex by varying width of flow path according to internal pressure by configuring rotatably formed partitioning part.

Another object of the present disclosure is to provide a collection device in which tilt angle of plate part is adjusted according to pressure of internal space by configuring plate part that rotates about rotation part.

Another object of the present disclosure is to provide a collection device that maximizes collection efficiency of specific substance to be collected by promoting generation of vortex in internal space of housing part through which fluid flows.

Another object of the present disclosure is to provide a collection device that promotes generation of vortex by causing difference in fluid velocity by configuring partitioning part that partitions internal space of housing part.

Another object of the present disclosure is to provide a collection device in which vortex is generated by difference in flow velocity between flow paths by dividing one flow path into plurality of flow paths having different flow path widths through partitioning part.

Another object of the present disclosure is to provide a collection device that generates vortex by partitioning part, thereby increasing collection efficiency and allowing substances that should be discharged to outside of collection part through discharge part to be smoothly discharged.

Another object of the present disclosure is to provide a collection device in which clockwise vortex is formed from inner circumferential surface of side surface of housing part toward center of housing part by forming partitioning part parallel to streamline rising toward outlet part side at position spaced apart by certain distance from inner circumferential surface of side surface of housing part, and by forming flow path width formed by inner circumferential surface of side surface of housing part and partitioning part to be relatively narrow, SO that fastest flow velocity occurs in corresponding flow path.

Another object of the present disclosure is to provide a collection device that forms vortex when rapidly rising fluid guided by partitioning part meets first wing part, by configuring first wing part which is inclined downward on upper side of partitioning part.

Another object of the present disclosure is to provide a collection device in which vortex phenomenon caused by fluid whose flow velocity is increased by partitioning part is maximized, by configuring first extension part extending downward from other end of first wing part.

Another object of the present disclosure is to provide a collection device that guides moving direction of fluid entering internal space of housing part from inlet part toward partitioning part, by configuring second wing part located on upper side of inlet part and inclined downward, and by configuring second extension part extending downward from other end of second wing part.

Another object of the present disclosure is to provide a collection device that prevents embers generated in scrubber, etc., from spreading to other places by allowing all fluid introduced into collection device to pass through fluid film, by configuring treatment fluid supply part that is inclined downward along second wing part so that treatment fluid falls into internal space.

Another object of the present disclosure is to provide a collection device that blocks problem of large fire spreading as flames move along piping when scrubber explosion occurs.

Another object of the present disclosure is to provide a collection device that can neutralize harmful gases to human body such as ammonia (NH₃), silane (SiH₄), etc., contained in fluid discharged from scrubber, etc., and remove fine particles such as fume contained in fluid.

Another object of the present disclosure is to provide a collection device that blocks spread of fire by providing treatment fluid in collection device installed on piping connecting scrubber and exhaust duct, so that piping made of PVC material, which is vulnerable to fire to prevent corrosion, does not become medium for fire spread.

Another object of the present disclosure is to provide a collection device that can separate and discharge corrosive liquid components contained in fluid treated in scrubber. etc., while blocking spread of fire through fluid film, by configuring a treatment fluid supply part that penetrates from outside to inside of collection part and drops treatment fluid in gravitational direction at specific position in internal space.

Another object of the present disclosure is to provide a collection device that enables separate washing by configuring treatment fluid supply part to penetrate housing part and be detachably coupled to housing part.

Another object of the present disclosure is to provide a collection device that allows all target fluid entering internal space through inlet part to pass through treatment fluid film by forming plurality of through-holes of treatment fluid supply part in rows and columns on lower surface of storage part, wherein through-holes of adjacent rows are arranged in staggered manner.

Another object of the present disclosure is to provide a collection device that allows treatment fluid contained in storage part to fall vertically along gravitational direction without moving attached to lower surface of storage part due to surface tension, etc., even if storage part is inclined, by configuring central axis direction of through-hole to be parallel to gravitational direction.

Another object of the present disclosure is to provide collection device that allows fluid to be introduced into internal space of housing part and allows agglomerated corrosive liquid components to gather in one place along inclined surface of housing part, by configuring inclined surface on lower side of housing part and allowing inlet part formed vertically from lower side to upper side direction to penetrate inclined surface and communicate with internal space.

Another object of the present disclosure is to provide a collection device of vertical type that can minimize space required for installation when installing collection device between scrubber and exhaust duct.

Another object of the present disclosure is to provide a collection device that minimizes space required for installing collection device and further enhances space efficiency by allowing inlet part to penetrate from lower side to upper side direction of housing part forming internal space and communicate with internal space.

Another object of the present disclosure is to provide a collection device that effectively prevents corrosion of piping by minimizing pressure drop of fluid by preventing bent portions when connecting piping to collection part.

Another object of the present disclosure is to provide a collection device that dramatically reduces amount of materials used, simplifies piping work, and facilitates maintenance after installation by enabling length of inlet part to be shortened without bent portions.

Another object of the present disclosure is to provide a collection device in which fluid vortex is actively formed at front end of outlet part by additional space, by configuring additional part that forms additional space in internal space of housing part.

Another object of the present disclosure is to provide a collection device that further enhances collection efficiency of specific substance by generating fluid vortex in internal space before fluid exits through outlet part, by collection device being formed parallel to outlet part on one surface of collection part where outlet part is formed.

Another object of the present disclosure is to provide a collection device that allows vortex to be generated by additional space by closing opened surface of body part by cap part when collection device is in operation, and allows inspection or easy cleaning of inside of collection device by separating cap part and opening one surface of body part when collection device is not in operation, by configuring cylindrical body part that forms additional space communicating with internal space and has one surface and other surface opened, and cap part detachably coupled to body part to open and close opened surface of body part.

Another object of the present disclosure is to provide a collection device that allows cap part to be easily fixed to or separated from body part as needed by configuring fixing part that fixes cap part to body part.

### Technical Solution

The present disclosure may be implemented by one or more embodiments having some or all of the following configurations.

According to an embodiment of the present disclosure, the present disclosure comprises a collection part forming an internal space and collecting specific component from target fluid entering the internal space, an inlet part connected to the collection part and introducing the target fluid into the internal space, a treatment fluid supply part connected to the collection part and supplying treatment fluid for collecting the specific component from the target fluid into the internal space, an outlet part connected to the collection part and discharging target fluid treated in the internal space to outside of the internal space, and a discharge part connected to the collection part and discharging fluid containing the collected specific component to outside of the internal space, the collection part comprising housing part forming the internal space, and a partitioning part partitioning the internal space so that fluid vortex that enhances collection efficiency is generated, wherein the partitioning part is formed rotatable so that the width of flow path can be changed.

According to another embodiment of the present disclosure, the partitioning part comprises a plate part guiding movement of fluid, and a rotating part enabling rotation of the plate part.

According to yet another embodiment of the present disclosure, the plate part rotates about the rotating part so that tilt angle is adjusted according to pressure of the internal space.

According to yet another embodiment of the present disclosure, the partitioning part partitions one flow path of the internal space into plurality of flow paths having different flow path widths to generate fluid vortex by difference in flow velocity between partitioned flow paths.

According to yet another embodiment of the present disclosure, the partitioning part is formed parallel to streamline in a direction ascending toward the outlet part.

According to yet another embodiment of the present invention, the partitioning part is formed at a position spaced apart from inner circumferential surface of side surface of housing part by certain distance, and forms the width of the flow path formed with the inner circumferential surface of side surface of the housing part among flow paths divided by partitioning part relatively narrow, so that fastest flow velocity is generated in flow path formed by inner circumferential surface of side surface of the housing part and the partitioning part.

According to yet another embodiment of the present disclosure, the collection part comprises a first wing part located on upper side of the partitioning part and formed in a shape to restrict flow of fluid ascending according to guidance of the partitioning part.

According to yet another embodiment of the present disclosure, the first wing part has one end coupled to inner circumferential surface of side surface of housing part, other end forming free end, and is formed to be inclined in downward direction.

According to yet another embodiment of the present disclosure, the collection part comprises a first extension part extending in downward direction from other end of the first wing part forming free end.

According to yet another embodiment of the present invention, the collection part comprises a second wing part located on upper side of the inlet part and formed in a shape to restrict flow of fluid ascending from the inlet part, and the second wing part has one end coupled to inner circumferential surface of side surface of housing part, other end forming free end, and is formed to be inclined in downward direction.

According to yet another embodiment of the present disclosure, the collection part comprises a second extension part extending in downward direction from other end forming free end of the second wing part.

According to yet another embodiment of the present disclosure, the treatment fluid supply part is formed to be inclined in downward direction along the second wing part, and comprises a storage part forming a receiving space in which the treatment fluid is stored, and a through-hole, which is a hole penetratingly formed in the storage part so that the treatment fluid stored in the receiving space falls into the internal space.

### Advantageous Effects

The present disclosure may achieve the following effects from the embodiment and configurations described below, as well as combinations and relationships of use thereof.

According to the present disclosure, the present disclosure provides a collection device that changes width of flow path according to internal pressure through a rotatably formed partitioning part to promote fluid vortex generation.

According to the present disclosure, the present disclosure provides a collection device in which tilt angle of a plate part is adjusted according to pressure of internal space by configuring plate part that rotates about rotation part.

According to the present disclosure, the present disclosure provides a collection device that maximizes collection efficiency of specific substance to be collected by promoting generation of vortex in internal space of housing part through which fluid flows.

According to the present disclosure, the present disclosure provides a collection device that promotes generation of vortex by causing difference in fluid velocity by configuring partitioning part that partitions internal space of housing part.

According to the present disclosure, the present disclosure provides a collection device in which vortex is generated by difference in flow velocity between flow paths by dividing one flow path into plurality of flow paths having different flow path widths through partitioning part.

According to the present disclosure, the present disclosure provides a collection device that generates vortex by a partitioning part, thereby increasing collection efficiency and allowing substances that should be discharged to outside of collection part through discharge part to be smoothly discharged.

According to the present disclosure, the present disclosure provides a collection device in which clockwise vortex is formed from inner circumferential surface of side surface of housing part toward center of housing part by forming partitioning part parallel to streamline rising toward outlet part side at a position spaced apart by certain distance from inner circumferential surface of side surface of housing part, and by forming flow path width formed by inner circumferential surface of side surface of housing part and partitioning part to be relatively narrow, so that fastest flow velocity occurs in corresponding flow path.

According to the present disclosure, the present disclosure provides a collection device that forms vortex when rapidly rising fluid guided by partitioning part meets a first wing part, by configuring a first wing part which is inclined downward on upper side of partitioning part.

According to the present disclosure, the present disclosure provides a collection device in which vortex phenomenon caused by fluid whose flow velocity is increased by partitioning part is maximized, by configuring a first extension part extending downward from other end of first wing part.

According to the present disclosure, the present disclosure provides a collection device that guides moving direction of fluid entering internal space of housing part from inlet part toward partitioning part, by configuring a second wing part located on upper side of inlet part and inclined downward, and by configuring a second extension part extending downward from other end of a second wing part.

According to the present disclosure, the present disclosure provides a collection device that prevents embers generated in a scrubber, etc., from spreading to other places by allowing all fluid introduced into the collection device to pass through a fluid film, by configuring a treatment fluid supply part that is inclined downward along the second wing part so that treatment fluid falls into an internal space.

According to the present disclosure, the present disclosure provides a collection device that blocks problem of a large fire spreading as flames move along piping when scrubber explosion occurs.

According to the present disclosure, the present disclosure provides a collection device that can neutralize harmful gases to human body such as ammonia (NH₃), silane (SiH₄), etc., contained in fluid discharged from a scrubber, etc., and remove fine particles such as fume contained in the fluid.

According to the present disclosure, the present disclosure provides a collection device that blocks spread of fire by providing treatment fluid in collection device installed on piping connecting scrubber and exhaust duct, so that piping made of PVC material, which is vulnerable to fire to prevent corrosion, does not become medium for fire spread.

According to the present disclosure, the present disclosure provides a collection device that can separate and discharge corrosive liquid components contained in fluid treated in scrubber, etc., while blocking spread of fire through fluid film, by configuring treatment fluid supply part that penetrates from outside to inside of collection part and drops treatment fluid in gravitational direction at specific position in internal space.

According to the present disclosure, the present disclosure provides a collection device that enables separate washing by configuring treatment fluid supply part to penetrate housing part and be detachably coupled to housing part.

According to the present disclosure, the present disclosure provides collection device that allows all target fluid entering internal space through inlet part to pass through treatment fluid film by forming plurality of through-holes of treatment fluid supply part in rows and columns on lower surface of storage part, wherein through-holes of adjacent rows are arranged in a staggered manner.

According to the present disclosure, the present disclosure provides a collection device that allows treatment fluid contained in storage part to fall vertically along gravitational direction without moving attached to lower surface of storage part due to surface tension, etc., even if storage part is inclined, by configuring central axis direction of a through-hole to be parallel to gravitational direction.

According to the present disclosure, the present disclosure provides a collection device that allows fluid to be introduced into internal space of housing part and allows agglomerated corrosive liquid components to gather in one place along inclined surface of housing part, by configuring inclined surface on lower side of housing part and allowing inlet part formed vertically from lower side to upper side direction to penetrate inclined surface and communicate with internal space.

According to the present disclosure, the present disclosure provides a collection device of vertical type that can minimize space required for installation when installing a collection device between a scrubber and an exhaust duct.

According to the present disclosure, the present disclosure provides a collection device that minimizes space required for installing collection device and further enhances space efficiency by allowing inlet part to penetrate from lower side to upper side direction of housing part forming internal space and communicate with internal space.

According to the present disclosure, the present disclosure provides a collection device that effectively prevents corrosion of piping by minimizing pressure drop of fluid by preventing bent portions when connecting piping to collection part.

According to the present disclosure, the present disclosure provides a collection device that dramatically reduces amount of materials used, simplifies piping work, and facilitates maintenance after installation by enabling length of an inlet part to be shortened without bent portions.

According to the present disclosure, the present disclosure provides a collection device in which fluid vortex is actively formed at a front end of an outlet part by additional space, by configuring additional part that forms additional space in internal space of housing part.

According to the present disclosure, the present disclosure provides a collection device that further enhances collection efficiency of specific substance by generating fluid vortex in internal space before fluid exits through outlet part, by being formed parallel to outlet part on one surface of collection part where outlet part is formed.

According to the present disclosure, the present disclosure provides a collection device that allows vortex to be generated by additional space when collection device is in operation by closing opened one surface of body part by cap part, and allows inspection or easy cleaning of inside of collection device by separating a cap part and opening one surface of body part when collection device is not in operation, by configuring a cylindrical body part that forms additional space communicating with internal space and has one surface and other surface opened, and cap part detachably coupled to body part to open and close opened one surface of body part.

According to the present disclosure, the present disclosure provides a collection device that allows cap part to be easily fixed to or separated from body part as needed by configuring fixing part that fixes cap part to body part.

### DESCRIPTION OF DRAWINGS

FIG. 1 is a diagram illustrating a conventional liquid collection device.

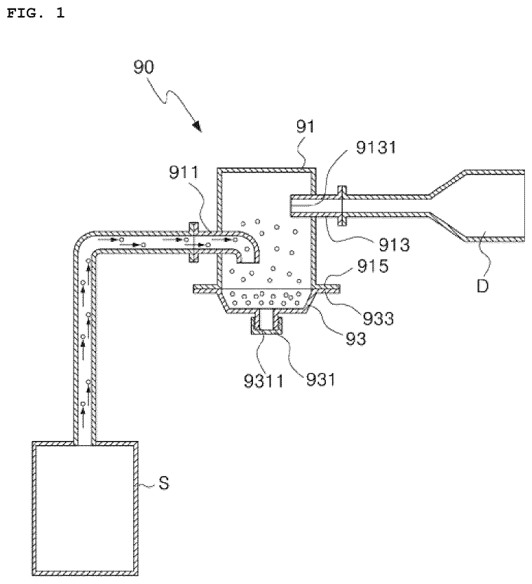

FIG. 2 is a diagram illustrating an installed state of a conventional liquid collection device.

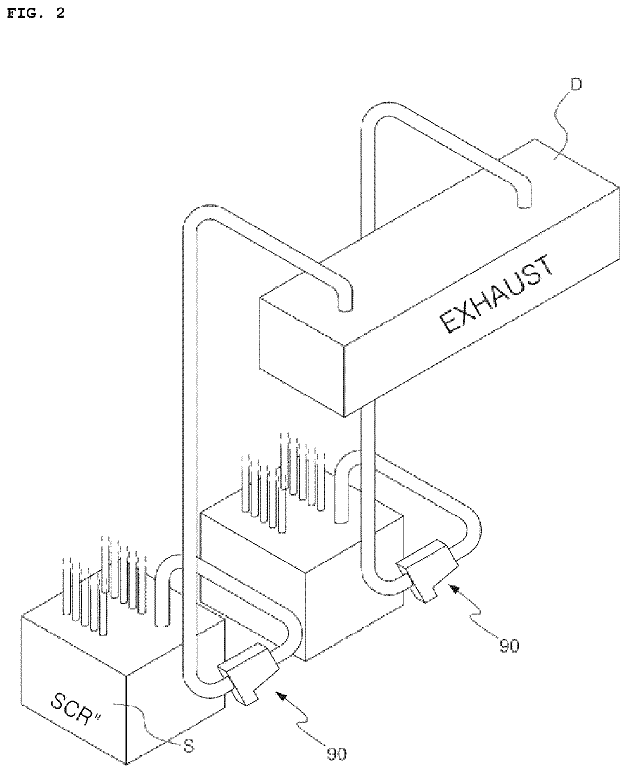

FIG. 3 is a diagram illustrating a collection device according to an embodiment of the present disclosure.

FIG. 4 is a cross-sectional view taken along line A-A′ of FIG. 3.

FIG. 5 is an operational state diagram of FIG. 4.

FIG. 6 is a diagram illustrating another embodiment of FIG. 4.

FIG. 7 is an operational state diagram of FIG. 6.

FIG. 8 is a diagram illustrating a collection device according to another embodiment of the present disclosure.

FIG. 9 is a partially exploded perspective view of FIG. 8.

FIG. 10 is a cross-sectional view taken along line B-B′ of FIG. 8.

FIG. 11 is an operational state diagram of FIG. 8.

FIG. 12 is a diagram illustrating another embodiment of FIG. 10.

FIG. 13 is an operational state diagram of FIG. 12.

FIG. 14 is a diagram illustrating an example of installed state of collection device of the present disclosure.

### BEST MODE FOR INVENTION

Hereinafter, preferred embodiments of collection device that increases collection efficiency using vortex of fluid according to present disclosure will be described in detail with reference to accompanying drawings. In describing the present disclosure below, detailed description of known functions or configurations will be omitted when it is determined that detailed description may unnecessarily obscure gist of the present disclosure. Unless specifically defined otherwise, all terms used in this specification have same general meanings as understood by those skilled in art to which present disclosure pertains, and if meanings of terms used in this specification conflict, they shall follow definitions used in this specification.

Collection device 1 of the present disclosure maximizes collection efficiency of specific substance to be collected by causing difference in fluid velocity in internal space of housing part through which fluid flows, or by creating additional space communicating with internal space, thereby promoting generation of a vortex.

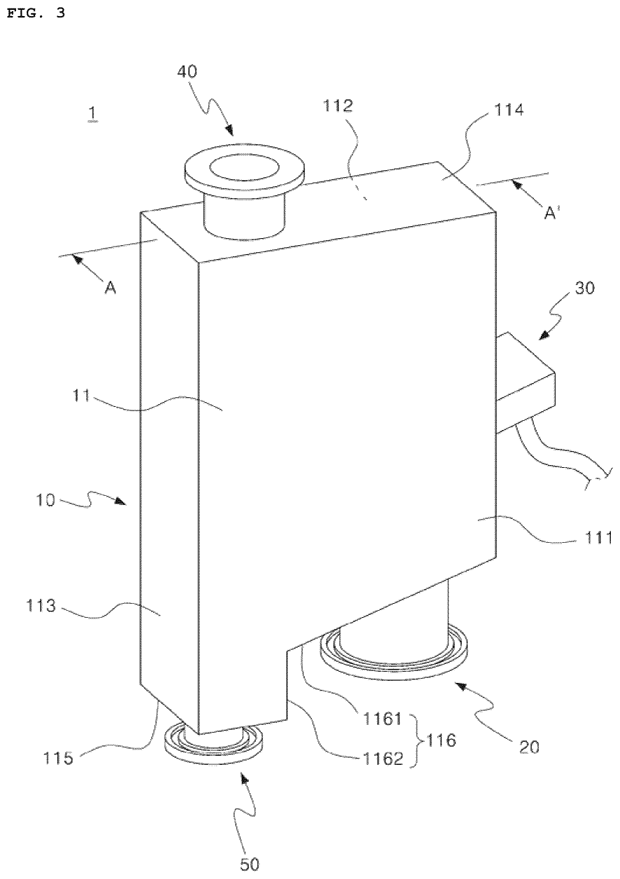

FIG. 3 is a diagram illustrating collection device 1 according to an embodiment of the present disclosure. Referring to FIG. 3, collection device 1 of an embodiment of the present disclosure comprises collection part 10, inlet part 20, treatment fluid supply part 30, outlet part 40, and discharge part 50.

The collection part 10 of the present disclosure is a configuration that forms internal space and collects specific component from target fluid that has entered the internal space. One side of the collection part 10 is connected to inlet part 20 to be described later, and other side of the collection part 10 is connected to outlet part 40 to be described later, so that corrosive liquid components can be collected from fluid introduced from scrubber, etc., and human-harmful gases can be neutralized. Fluid introduced through scrubber, etc., may contain strong corrosive substances such as hydrofluoric acid, and the collection part 10 collects these liquid components, thereby preventing pipe corrosion by ensuring that no corrosive liquid components exist in exhausted fluid, and functions to neutralize harmful substances such as ammonia (NH3), silane (SiH4), etc.

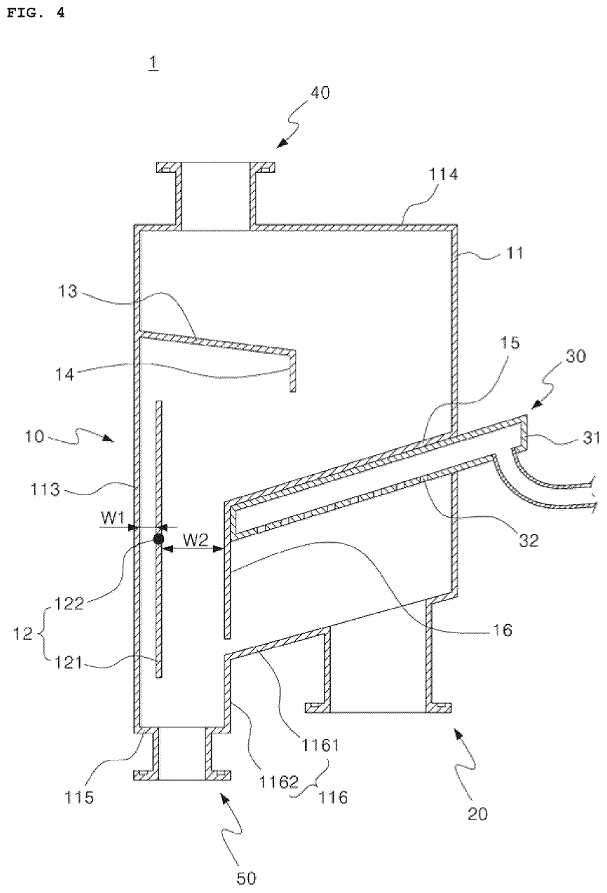

FIG. 4 is a cross-sectional view taken along line A-A′ of FIG. 3, and referring to FIG. 4, the collection part 10 comprises housing part 11, partitioning part 12, first wing part 13, first extension part 14, second wing part 15, and second extension part 16.

The housing part 11 of the present disclosure forms the internal space and forms overall external shape of the collection device 1. Referring to FIG. 3, the housing part 11 may have an overall rectangular box shape, but may have a shape in which part of lower side is removed to form inclined surface. Preferably, inlet part 20 to be described later, is coupled to lower side of the housing part 11, and outlet part 40 to be described later, is coupled to upper side of the housing part 11, so that fluid introduced through inlet part 20 passes through internal space of the housing part 11 and is discharged through outlet part 40 to be described later. Since corrosive liquid components, human-harmful gases, etc., are removed within the housing part 11, corrosive liquid components, human-harmful gases, etc., exist in the fluid introduced from inlet part 20, but corrosive liquid components, human-harmful gases, etc., do not exist in fluid discharged through outlet part 40.

Referring to FIG. 3, the housing part 11 may be divided into front surface 111, rear surface 112, side surface 113, upper surface 114, lower surface 115, and inclined surface 116.

The front surface 111 is a vertical surface located on front side of the housing part 11 and refers to surface indicated in FIG. 3.

The rear surface 112 is a surface located on opposite side of the front surface 111 and refers to a vertical surface located on rear side of the housing part 11.

The side surface 113 is a surface connecting the front surface 111 and the rear surface 112 and refers to a vertical surface located on left and right sides of the housing part 11.

The upper surface 114 is a horizontal surface located on upper side of the housing part 11 and refers to a portion to which outlet part 40 to be described later is coupled.

The lower surface 115 is a surface located on lower side of the housing part 11 and is a portion connected to inclined surface 116 to be described later, and as shown in FIG. 3, discharge part 50 to be described later is coupled to the lower surface 115 so that corrosive liquid components, treatment fluid, etc., gathered on the lower surface 115 can be discharged to outside of the housing part 11. Although FIG. 3 and FIG. 4 illustrate the lower surface 115 forming a horizontal surface, to facilitate gathering of fluid on lower surface 115 and discharge of gathered fluid through discharge part 50, an inclined surface may be formed such that periphery of discharge part 50 is raised so that fluid naturally flows toward discharge part 50 side.

The inclined surface 116 is a portion connected to the lower surface 115 at an incline, and by configuring the inclined surface 116 on lower side of the housing part 11 and allowing inlet part 20 to be described later formed vertically from lower side to upper side direction, to penetrate the inclined surface 116 and communicate with internal space of the housing part 11, fluid is allowed to be introduced into internal space of the housing part 11, and agglomerated liquid components can gather on the lower surface 115 along the inclined surface 116 of the housing part 11. For this purpose, the inclined surface 116 may comprise first inclined surface 1161 and second inclined surface 1162, as shown in FIG. 3 and FIG. 4.

The first inclined surface 1161 forms a certain angle, and one end thereof is a portion connected to the side surface 113, and preferably, it refers to a surface through which inlet part 20 to be described later penetrates. As shown in FIG. 3 and FIG. 4, tilt angle of the first inclined surface 1161 may be smaller than tilt angle of second inclined surface 1162 to be described later, and alternatively, tilt angle of the first inclined surface 1161 may be configured to be equal to or larger than tilt angle of second inclined surface 1162.

The second inclined surface 1162 forms a certain angle, and one end thereof is connected to other surface of the first inclined surface 1161, and other end thereof is a portion connected to the lower surface 115. According to FIG. 3 and FIG. 4, the second inclined surface 1162 is expressed as forming an angle of 90 degrees, but it is not necessarily limited thereto, and may have various angles as long as it can guide fluid toward the lower surface 115 side.

The partitioning part 12 is a configuration that partitions the internal space so that fluid vortex that enhances collection efficiency is generated, and is characterized by dividing one flow path of the internal space into plurality of flow paths having different flow path widths (W1<W2) to generate fluid vortex by difference in flow velocity between divided flow paths. Preferably, as shown in FIG. 4, the partitioning part 12 may be configured to have a plate-like shape formed parallel to streamline in a direction ascending toward outlet part 40 side to be described later. One side of the plate-like partitioning part 12 may be coupled to front surface 111 of the housing part 11, and other side of the partitioning part 12 may be coupled to rear surface 112 of the housing part 11.

More preferably, the partitioning part 12 is formed at a position spaced apart from inner circumferential surface of side surface 113 of the housing part 11 by certain distance W1, and among flow paths divided by partitioning part 12, flow path width WI formed with inner circumferential surface of side surface 113 of the housing part 11 is formed relatively narrow (W1<W2), so that fastest flow velocity is generated in flow path formed by inner circumferential surface of side surface 113 of the housing part 11 and the partitioning part 12. Accordingly, clockwise vortex may be formed from inner circumferential surface of side surface 113 of the housing part 11 toward center of housing part, thereby increasing collection efficiency of specific substances and allowing substances that should be discharged to outside of the collection part 10 through discharge part 50 to be described later to be smoothly discharged.

The first wing part 13 is a configuration formed in a shape to restrict flow of fluid ascending according to guidance of the partitioning part 12, located on upper side of the partitioning part 12. Preferably, the first wing part 13 may be a plate-like member whose one end is coupled to inner circumferential surface of side surface 113 of the housing part 11, other end forms a free end, and is inclined in a downward direction. By configuring the first wing part 13 inclined in a downward direction on upper side of the partitioning part 12, a vortex is formed when fluid rapidly ascending due to the partitioning part 12 meets the first wing part 13.

The first extension part 14 is a configuration extending in a downward direction from other end of the first wing part 13 that forms a free end. As shown in FIG. 4, by configuring the first extension part 14, vortex phenomenon caused by fluid whose flow velocity is increased by the partitioning part 12 can be maximized. Preferably, as shown in FIG. 4, the first extension part 14 may be formed to extend vertically from other end of the first wing part 13.

The second wing part 15 is a configuration formed in a shape to restrict flow of fluid ascending from inlet part 20 to be described later, located on upper side of inlet part 20. One end of the second wing part 15 may be coupled to inner circumferential surface of side surface 113 of the housing part 11, and other end may form a free end and be inclined in a downward direction. The second wing part 15 guides moving direction of fluid entering internal space of the housing part 11 from inlet part 20 to be described later, toward the partitioning part 12.

The second extension part 16 is a configuration extending in a downward direction from other end of the second wing part 15 that forms a free end. It is preferable that end of the second extension part 16 is configured not to meet inclined surface 116 of the housing part 11 so that fluid can move in space between the second extension part 16 and inclined surface 116 of the housing part 11. Preferably, as shown in FIG. 4, the second extension part 16 may be formed to extend vertically downward from other end of the second wing part 15.

The inlet part 20 is a configuration connected to the collection part 10 to introduce the target fluid into the internal space. Preferably, fluid treated in scrubber, etc., can enter internal space of the housing part 11 through the inlet part 20. Shape of the inlet part 20 is not limited to any specific shape, but as shown in FIG. 3, it may be configured in a cylindrical shape with an open upper surface and a lower surface. The inlet part 20 extends vertically from lower side to upper side direction and penetrates inclined surface 116 of the housing part 11 to communicate with internal space of the housing part 11. The inlet part 20 of collection device 1 of the present disclosure is configured as a straight vertical pipe without being bent, thereby preventing problems of load application when fluid discharged through scrubber, etc., passes through the inlet part 20 and corrosion due to a large pressure drop. In addition, since length of inlet part 20 can be shortened without bent portions, amount of materials used is dramatically reduced, piping work is simplified, and maintenance after installation becomes easy.

The treatment fluid supply part 30 is a configuration connected to the collection part 10 to supply treatment fluid for collecting the specific component from the target fluid into the internal space. Preferably, the treatment fluid supply part 30 is formed to penetrate side surface 113 of the housing part 11, is detachably coupled to the housing part 11 for easy separate washing, and can be seen as a configuration that closely contacts lower surface of the second wing part 15. Fluid film or fluid curtain that blocks fire spread can be formed by the treatment fluid supply part 30, and the treatment fluid is not limited to any specific fluid, but preferably, it may be composed of water (H20), and therefore, fluid film formed by the treatment fluid supply part 30 may be a water film. In addition, the treatment fluid may be composed of a neutralizing agent that neutralizes harmful gases. Used treatment fluid can be continuously used through a recycling process.

The treatment fluid supply part 30, as shown in FIG. 4, is brought into close contact with lower surface of the second wing part 15, and accordingly, even if the treatment fluid supply part 30 is configured, internal space of f the housing part 11 does not significantly decrease, SO that sufficient liquid collection is achieved without increasing size of collection device 1.

The treatment fluid supply part 30 is formed to be inclined in a downward direction along the second wing part 15. By allowing treatment fluid to fall into internal space through the treatment fluid supply part 30, all fluid introduced into the collection device 1 is made to pass through fluid film, thereby preventing embers generated in scrubber, etc., from spreading to other places. In addition, when an explosion of scrubber, etc., occurs, problem of a large fire spreading as flames move along piping is fundamentally blocked. Furthermore, it neutralizes human-harmful gases such as ammonia (NH3), silane (SiH4), etc., contained in fluid discharged from scrubber, etc., and removes fine particles such as fume contained in fluid.

Referring to FIG. 4, the treatment fluid supply part 30 comprises storage part 31 and through-hole 32.

The storage part 31 is a configuration that forms a receiving space in which the treatment fluid is stored and may be detachably coupled to the housing part 11. Preferably, as shown in FIG. 4, the storage part 31 may be formed in a box shape with empty interior. The storage part 31 penetrates side surface 113 of the housing part 11 and is formed to be inclined in a downward direction to induce a smooth flow of treatment fluid.

Through-hole 32 is a hole penetratingly formed in the storage part 31 so that the treatment fluid stored in the receiving space falls into the internal space. Preferably, to prevent leakage of treatment fluid to outside of the housing part 11, the through-hole 32 may be formed only in portion of lower surface of the storage part 31 that is inserted into internal space of the housing part 11. Preferably, by forming plurality of through-holes 32 of the treatment fluid supply part 30 in rows and columns on lower surface of the storage part 31, wherein through-holes 32 of adjacent rows are arranged in a staggered manner, all target fluid entering internal space of the housing part 11 through the inlet part 20 is allowed to pass through treatment fluid film. Also, by configuring central axis direction of the through-hole 32 to be parallel to gravitational direction, even if the storage part 31 is inclined, treatment fluid contained in the storage part 31 can fall vertically along gravitational direction without moving attached to lower surface of the storage part 31 due to surface tension, etc.

The outlet part 40 is a configuration connected to the collection part 10 to discharge target fluid treated in the internal space to outside of the internal space, and discharges fluid from which corrosive liquid components, human-harmful gases, etc., have been removed in the collection part 10. Shape of the outlet part 40 is not limited to any specific shape, but preferably, it may be configured in a cylindrical shape with an open upper surface and a lower surface. As described above, the inlet part 20 is configured to penetrate inclined surface 116 of the housing part 11, but it is preferable to view the outlet part 40 as communicating with internal space of the housing part 11 and extending vertically upward from upper surface 114 of the housing part 11. The outlet part 40 of collection device 1 of the present disclosure can also be configured in a straight vertical pipe shape without being bent, thus, even if collection device 1 is installed between scrubber and exhaust duct, large installation space is not required, and problems of load application and pressure drop phenomenon due to vertical connection of pipes are prevented. In addition, it prevents foreign substances from adhering to inner wall of pipe to form scale, can block internal corrosion of pipe by corrosive liquid components, and can neutralize human-harmful gases.

The discharge part 50 is a configuration connected to the collection part 10 to discharge fluid containing the collected specific component to outside of the internal space. That is, the discharge part 50 is coupled to lower surface 115 of the housing part 11 and refers to a configuration that drains collected corrosive liquid components and the treatment fluid to outside. For this purpose, the discharge part 50 may be configured in a cylindrical shape with an open upper surface and a lower surface, and preferably, may be configured in a cylindrical shape. Corrosive liquid components agglomerated by colliding with the first wing part 13, etc., fall due to gravity and gather on lower surface 115 of the housing part 11, and since the discharge part 50 is configured on such lower surface 115, the collected specific component is discharged to outside of the housing part 11. In addition, treatment fluid continuously supplied to internal space of the housing part 11 to form a fluid film for preventing fire spread falls due to gravity, and fallen treatment fluid gathers in the discharge part 50 and is discharged out. of the housing part 11, and can be reused for recirculation after a filtering process, etc.

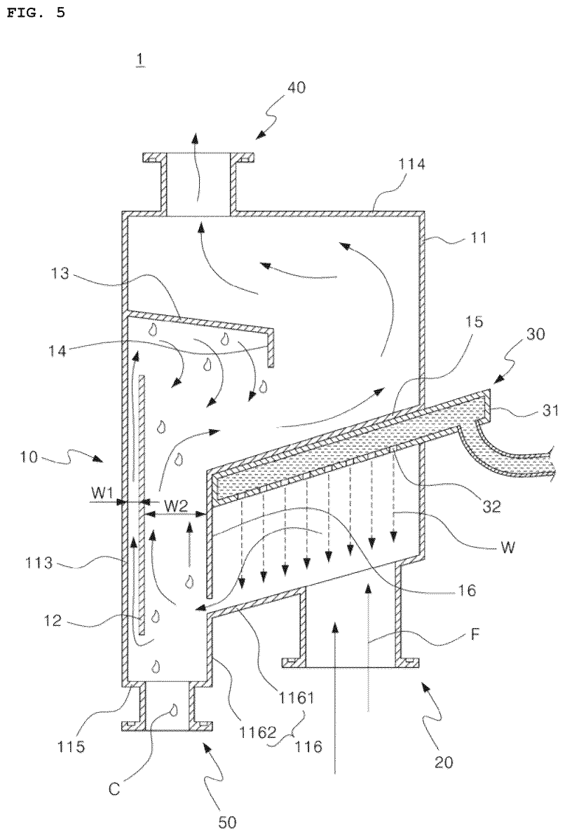

FIG. 5 is an operational state diagram of FIG. 3. Referring to FIG. 5, fluid F entering internal space of the housing part 11 through the inlet part 20 meets treatment fluid W falling from the treatment fluid supply part 30, thereby not only preventing fire spread, but also neutralizing human-harmful gases such as ammonia (NH3), silane (SiH4), etc., contained in fluid, and removing fine particles such as fume, etc., contained in fluid.

Thereafter, fluid F moves in downward direction guided by the second wing part 15 and second extension part 16, and flow path that fluid F encounters after passing between end of the second extension part 16 and inclined surface 116 of the housing part 11 can be divided into two flow paths by the partitioning part 12, as shown in FIG. 5. Since the partitioning part 12 is offset toward side surface 113 of the housing part 11, width W1 of flow path located close to side surface 113 side is formed narrower than width W2 of other flow path (W1<W2), thereby expressing faster fluid F flow velocity in flow path having flow path width of W1.

That is, velocity of fluid F passing through flow path having width of W1 becomes faster than velocity of fluid F passing through flow path having width of W2, and since first wing part 13 inclined in downward direction is located on upper side of the partitioning part 12, vortex as shown in FIG. 5 is generated by fluid F that has passed through flow path having width of W1.

When a negative pressure is generated on the outlet part 40 side to suck in fluid F, even though collected liquid components C should be discharged toward the discharge part 50 side, a problem may occur in that they cannot exit out of the housing part 11 through the discharge part 50 as pressure difference increases due to the negative pressure.

To solve such problem, the present disclosure, as shown in FIG. 5, forms a clockwise vortex by fluid F that has passed through flow path having width of W1, thereby generating a flow opposite to flow of fluid F ascending through flow path having width of W2. This allows smooth discharge of substance C through the discharge part 50 while increasing collection efficiency.

Through such process, fluid F from which specific component C has been removed moves out of housing part 11 through outlet part 40 formed on upper surface 114 of the housing part 11.

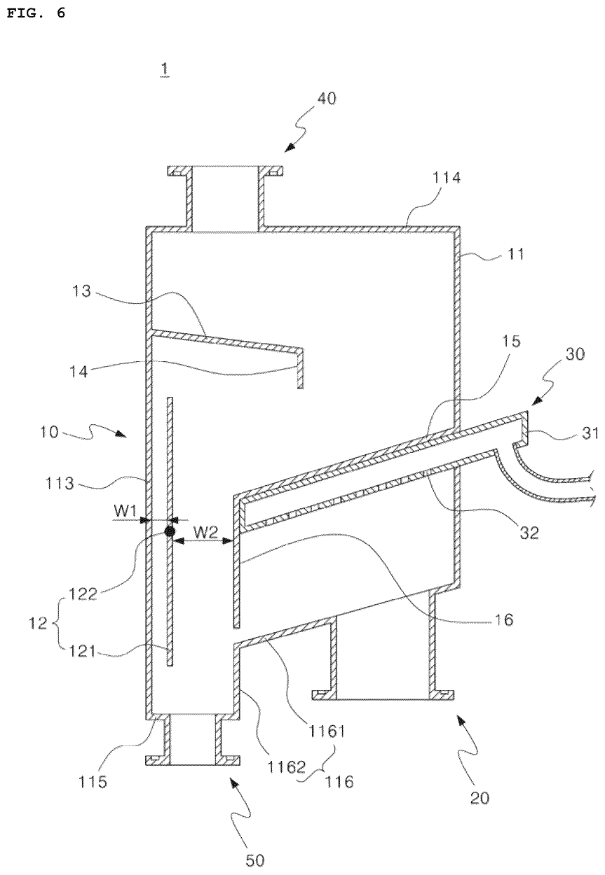

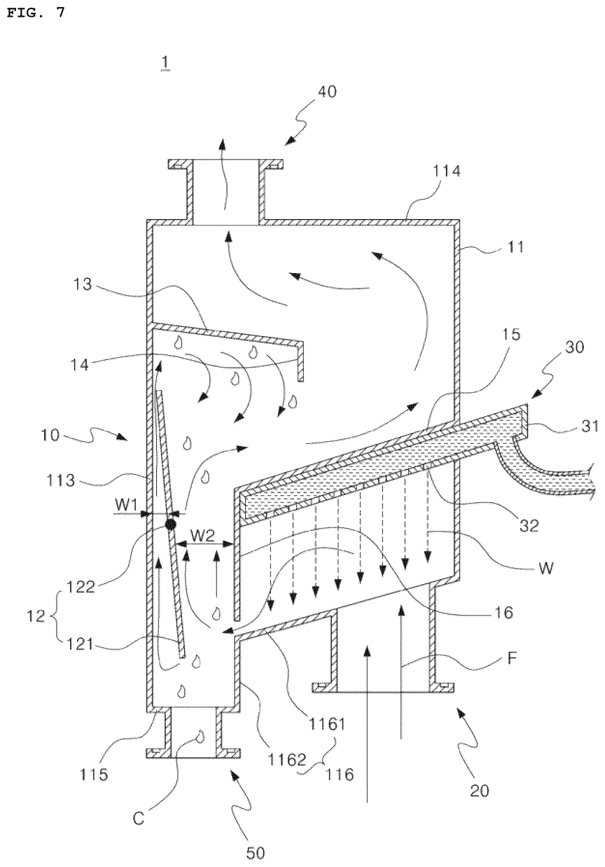

FIG. 6 is a diagram illustrating another embodiment of FIG. 4, and FIG. 7 is an operational state diagram of FIG. 6, and referring to FIG. 6 and FIG. 7, in this embodiment, the partitioning part 12 is rotatably formed, so that flow path width can be varied. For such purpose, the partitioning part 12 is configured to comprise plate part 121 and rotating part 122.

The plate part 121 is a configuration for guiding movement of fluid, and preferably, as shown in FIG. 6, may be configured in a plate-like shape. The plate part 121 is rotatable about rotating part 122 to be described later, so that its tilt angle can be adjusted according to pressure of the internal space. In FIG. 6, plate part 121 is formed parallel to streamline in direction ascending toward outlet part 40 side, but in FIG. 7, there is a difference in that the plate part 121 is rotated counterclockwise and configured to be inclined. According to such rotation of plate part 121, on upper side of partitioning part 12, distance W1 from inner circumferential surface of side surface 113 of the housing part 11 becomes narrower compared to FIG. 6, and on lower side of partitioning part 12, distance W1 from inner circumferential surface of side surface 113 of the housing part 11 becomes wider compared to FIG. 6. Conversely, if the plate part 121 is rotated clockwise and inclined, W1 distance on upper side of partitioning part 12 may become wider compared to FIG. 6, and WI distance on lower side of partitioning part 12 may become narrower compared to FIG. 6. Through this, the present disclosure can further promote fluid vortex by adjusting rotation angle of the plate part 121 according to pressure of internal space.

The rotating part 122 is a configuration that enables rotation of the plate part 121, and preferably, may be formed on longitudinal center of the plate part 121. Although not shown, rotation of the rotating part 122 can be performed by operating butterfly valve, etc., exposed to outside of the housing part 11. Therefore, when user determines that it is necessary to change width of flow path according to pressure of internal space, user operates an external valve, etc., to rotate the rotating part 122, and due to this rotation of the rotating part 122, tilt angle of the plate part 121 changes, thereby changing the distances W1, W2 as shown in FIG. 7.

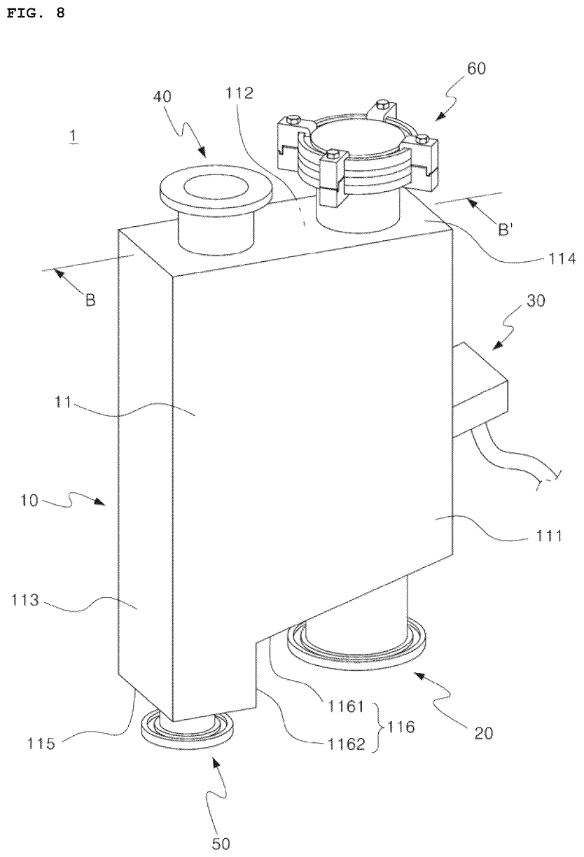

FIG. 8 is a diagram illustrating a collection device according to another embodiment of the present disclosure, and referring to FIG. 8, the embodiment of FIG. 8 is characterized in that an additional part 60 is configured, unlike previously described embodiment, hereinafter, the newly added additional part 60 will be described.

### The Additional Part 60 Is a Configuration That Forms

additional space in the internal space so that fluid vortex that enhances collection efficiency is generated, and it is formed on upper surface 114 of housing part 11 of the collection part 10 where the outlet part 40 is formed, parallel to the outlet part 40, and is characterized by generating a fluid vortex in internal space before fluid exits through the outlet part 40. Due to additional space formed by the additional part 60, fluid vortex can be actively formed at front end of the outlet part 40, thereby further increasing collection efficiency of specific substances.

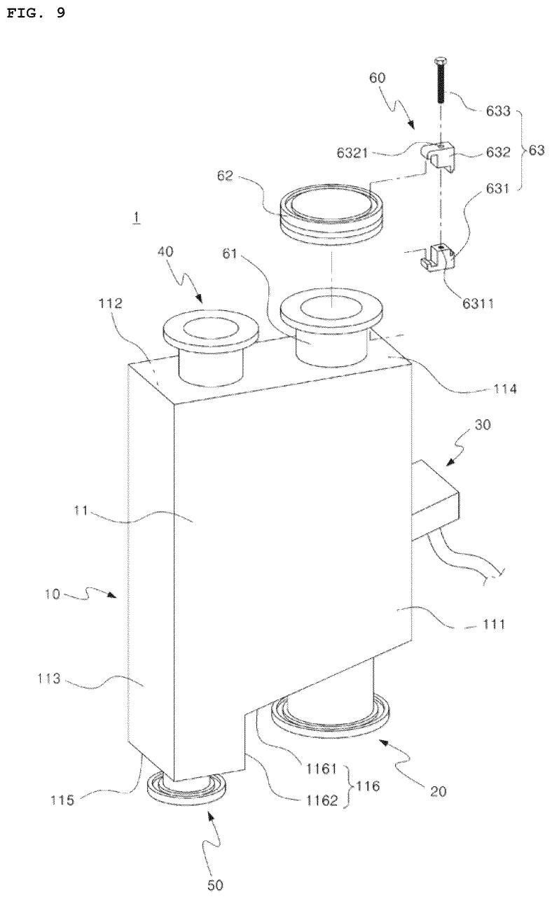

FIG. 9 is a partially exploded perspective view of FIG. 8, and referring to FIG. 9, the additional part 60 comprises a body part 61, a cap part 62, and a fixing part 63.

The body part 61 refers to a cylindrical configuration that forms additional space communicating with the internal space and has one surface and other surface opened. Although FIG. 9 illustrates the body part 61 as cylindrical, the body part 61 is not necessarily limited to this shape and may also be configured in a square pipe shape, etc. A flange may be formed on the body part 61 to facilitate coupling with a cap part 62 which will be described later.

The cap part 62 refers to a configuration detachably coupled to the body part 61 to open and close opened one surface of the body part 61. For this purpose, the cap part 62 may be configured in a shape that forms an empty space inside and has an opened lower surface. When the collection device 1 is in operation, opened one surface of the body part 61 is closed by the cap part 62 so that vortex is generated by additional space, and when the collection device 1 is not in operation, the cap part 62 is separated to open one surface of the body part 61, thereby allowing inspection or easy cleaning of inside of the collection device 1.

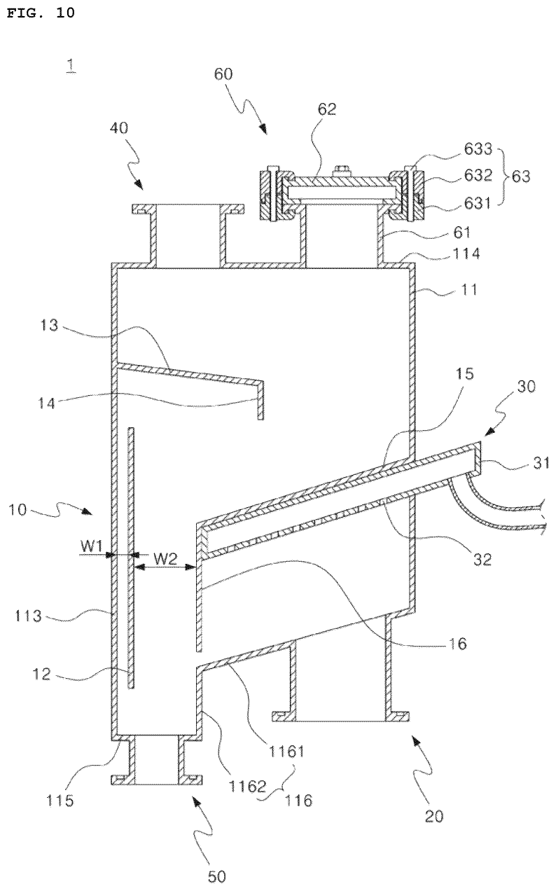

he fixing part 63 is a configuration that fixes the cap part 62 to the body part 61, and by configuring the fixing part 63, the cap part 62 can be easily fixed to or separated from the body part 61 as needed. Shape of the fixing part 63 is not limited to any specific shape, and for example, it may be configured in a shape as shown in FIG. 9. FIG. 9 is a partially exploded perspective view of FIG. 8, and FIG. 10 is a cross-sectional view taken along line B-B′ of FIG. 8, and referring to FIG. 9 and FIG. 10, the fixing part 63 comprises first fixing body 631, second fixing body 632, and fastening means 633.

The first fixing body 631 is formed in a shape to grip the body part 61 and comprises a first fixing hole 6311 penetrating from one surface to other surface. Female screw thread complementary to male screw thread formed on outer circumferential surface of fastening means 633 which will be described later, may be formed on inner circumferential surface of the first fixing hole 6311.

The second fixing body 632 is formed in a shape to grip the cap part 62 and comprises a second fixing hole 6321 penetrating from one surface to other surface. A female screw thread complementary to a male screw thread formed on outer circumferential surface of fastening means 633 which will be described later, may also be formed on inner circumferential surface of the second fixing hole 6321.

The fastening means 633 is a configuration that is fastened to the first fixing hole 6311 and the second fixing hole 6321 to couple the first fixing body 631 and the second fixing body 632, and preferably, the fastening means 633 may be a bolt with a screw thread formed on its outer circumferential surface.

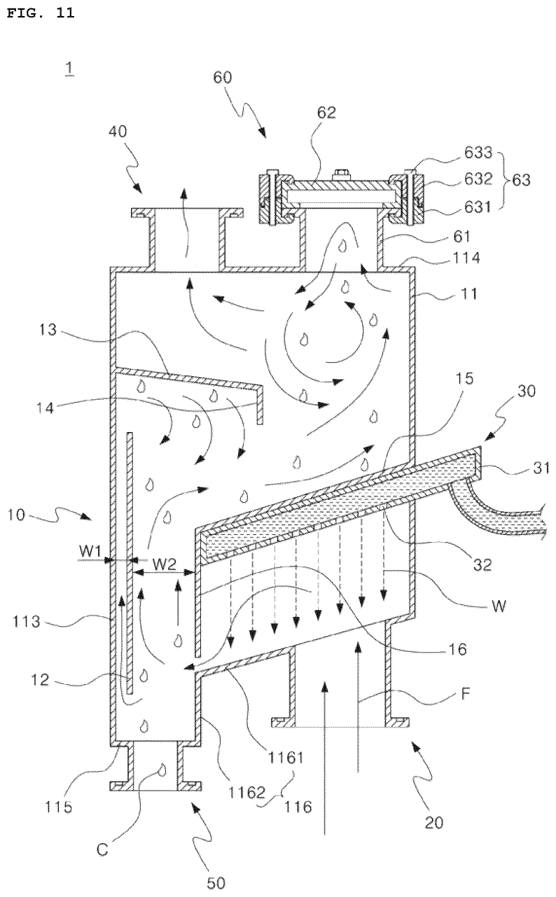

FIG. 11 is an operational state diagram of FIG. 8, and hereinafter, an operational state for this embodiment will be described referring to FIG. 11.

Since FIG. 11 is formed by adding the additional part 60 to operational state diagram of FIG. 5 described above, vortex phenomenon by the partitioning part 12 that occurred in FIG. 5 appears as it is. Whereas in FIG. 5, only fluid F vortex by the partitioning part 12, the first wing part 13, and the first extension part 14 occurred, in FIG. 11, after vortex of FIG. 5 occurs primarily, secondary vortex as shown in FIG. 11 is generated by additional space inside the body part 61 formed by the additional part 60.

That is, according to the embodiment of FIG. 11, fluid F from which specific component C has been removed by primary vortex is not immediately discharged through outlet part 40, instead, as internal space suddenly expands due to additional space encountered during movement, secondary vortex is formed by flow of fluid trying to move toward additional space side, and in this process, residual specific component C can be removed once more.

In collection device 1 of FIG. 11, the additional part 60 not only functions to generate secondary vortex, but also facilitates maintenance by allowing cap part 62 of the additional part 60 to be opened to inspect or clean inside of apparatus when collection device 1 is not in operation.

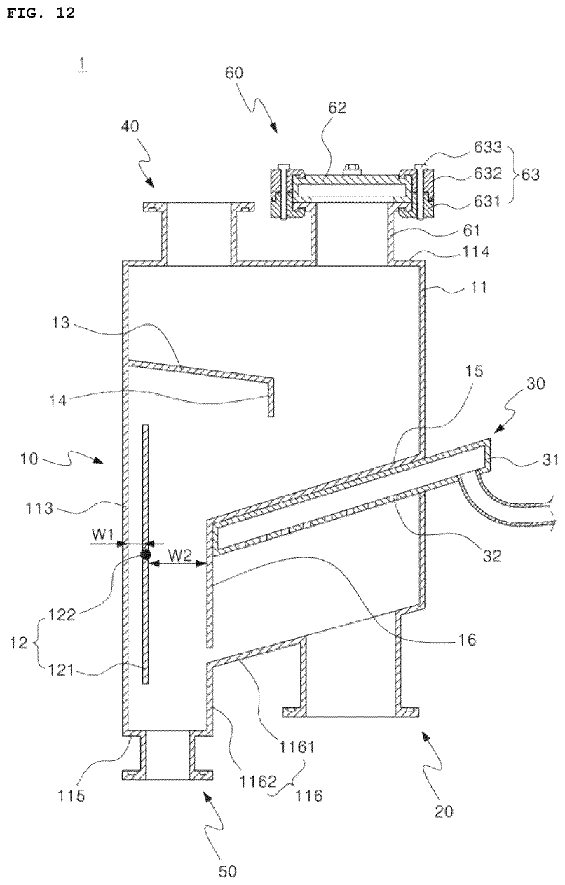

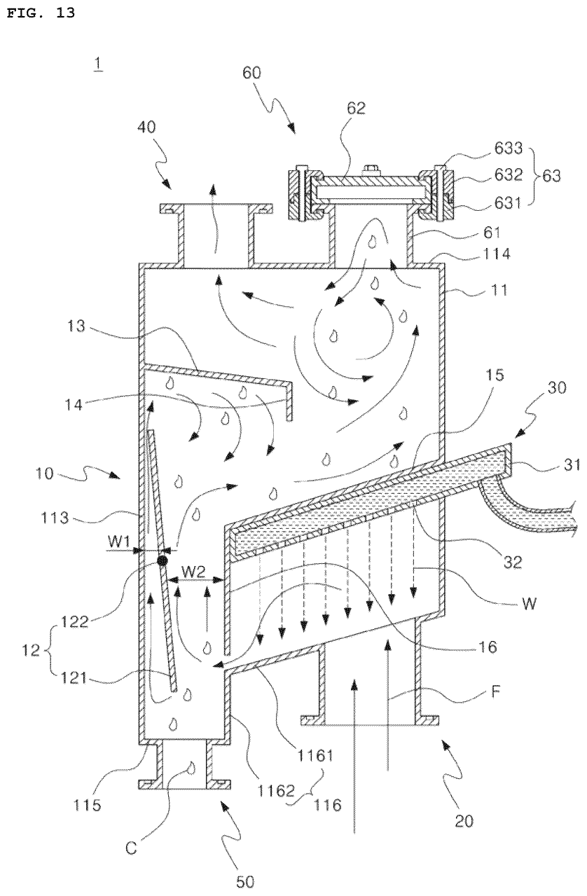

FIG. 12 is a diagram illustrating another embodiment of FIG. 10, and FIG. 13 is an operational state diagram of FIG. 12, and as described above, the partitioning part 12 may be configured to be rotatable by including the plate part 121 and rotating part 122. By operating butterfly valve, etc., exposed to outside of the housing part 11 to rotate the rotating part 122 counterclockwise, distance W1 from inner circumferential surface of side surface 113 of the housing part 11 on upper side of partitioning part 12 is made relatively narrow, and distance W1 from inner circumferential surface of side surface 113 of the housing part 11 on lower side of the partitioning part 12 is made relatively wide, or alternatively, by rotating the rotating part 122 clockwise, distance W1 from inner circumferential surface of side surface 113 of housing part 11 on upper side of the partitioning part 12 can be made relatively wide, and distance W1 from inner circumferential surface of side surface 113 of the housing part 11 on lower side of partitioning part 12 can be made relatively narrow.

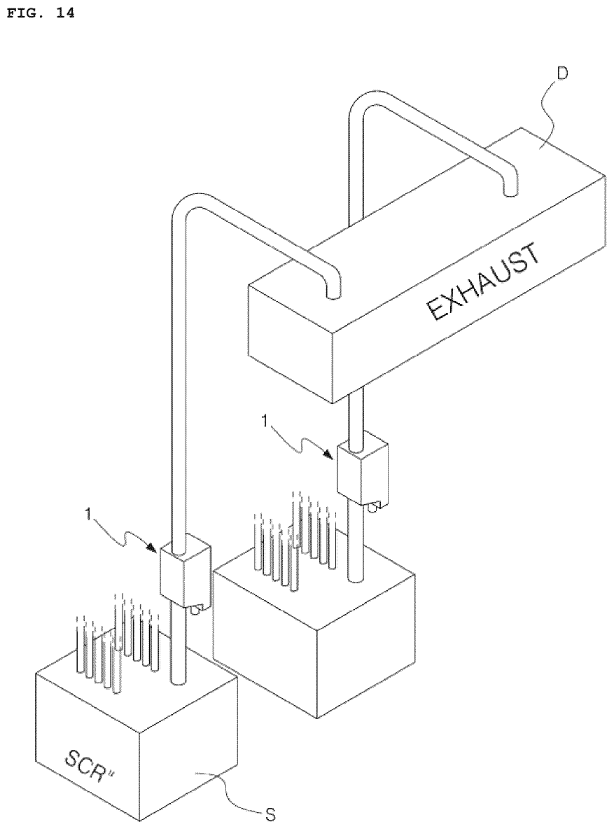

FIG. 14 is a diagram illustrating an example of installed state of collection device 1 of the present disclosure, and according to an embodiment of the present disclosure, by configuring vertical type collection device 1, space required for installation when installing collection device 1 between scrubber S and exhaust duct D can be minimized.

Although FIG. 14 illustrates that collection device 1 of the present disclosure is installed outside the scrubber, the present disclosure is not necessarily limited to installing collection device 1 of the present disclosure only outside the scrubber S, and it can also be installed inside scrubber S. That is, in the present disclosure, it may also be possible to locate collection device 1 inside scrubber S, so that collection device 1 installed inside scrubber S collects and treats fluid to be discharged by operation of scrubber S and then discharges it.

Collection device 1 of the present invention is configured such that the inlet part 20 penetrates from a lower side of the housing part 11, which forms an internal space, in an upward direction so as to be in fluid communication with the internal space, thereby minimizing the space required for installing the collection device 1 and further enhancing space efficiency. By ensuring that no bent portions are formed when connecting piping to the collection part 10, it is possible to provide a collection device 1 that minimizes pressure drop of the fluid and effectively prevents corrosion of the piping. Furthermore, as the length of the inlet 20 can be shortened without bent portions, it is possible to provide a collection device 1 that drastically reduces material usage, simplifies piping work, and facilitates post-installation maintenance.

The description provides an exemplary embodiment of the present disclosure, and the present disclosure may be used in other various combination, changes, and environments. That is, the present disclosure may be changed or modified within the scope of the present disclosure described herein, a range equivalent to the description, and/or within the knowledge or technology in the related art. The embodiments show an optimum state for achieving the spirit of the present disclosure, and various modifications required for specific applications and uses of the present disclosure are also possible. Therefore, the detailed description of the present disclosure is not intended to limit the present disclosure in the embodiment. In addition, the claims should be construed as comprising other embodiments.

1. A collection device that changes width of flow path according to pressure comprising:
a collection part forming an internal space and collecting specific component from target fluid introduced into the internal space;
an inlet part connected to the collection part and introducing the target fluid into the internal space;
a treatment fluid supply part connected to the collection part and supplying treatment fluid for collecting the specific component from the target fluid into the internal space;
an outlet part connected to the collection part and discharging the target fluid treated in the internal space to outside; and
a discharge part connected to the collection part and discharging fluid containing the specific component collected to outside of the internal space,
the collection part comprising:
a housing part forming the internal space; and
a partitioning part partitioning the internal space to generate fluid vortex, which increases collection efficiency,
wherein the partitioning part is formed rotatable so that the width of flow path can be changed.

2. A collection device that changes width of flow path according to pressure of claim 1,
wherein the partitioning part comprises a plate part guiding movement of fluid, and a rotating part enabling rotation of the plate part.

3. The collection device that changes width of flow path according to pressure of claim 2,
wherein the plate part rotates about the rotating part so that the tilt angle thereof is adjusted according to pressure of the internal space.

4. The collection device that changes width of flow path according to pressure of claim 1,
wherein the partitioning part partitions a flow path of the internal space into plurality of flow paths having different flow path widths, thereby generating fluid vortex by difference in flow velocity between partitioned flow paths.

5. The collection device that changes width of flow path according to pressure of claim 4,
wherein the partitioning part is formed parallel to streamline in a direction ascending toward the outlet part.

6. The collection device that changes width of flow path according to pressure of claim 5,
wherein the partitioning part is formed at a position spaced apart from the inner circumferential surface of side surface of the housing part by certain distance,
and forms the width of the flow path formed with the inner circumferential surface of side surface of the housing part among flow paths divided by the partitioning part relatively narrow, so that fastest flow velocity is generated in flow path formed by inner circumferential surface of side surface of the housing part and the partitioning part.

7. The collection device that changes width of flow path according to pressure of claim 1,
wherein the collection part comprises a first wing part located on upper side of the partitioning part and formed in a shape to restrict flow of fluid ascending according to guidance of the partitioning part.

8. The collection device that changes width of flow path according to pressure of claim 7,
wherein the first wing part has one end coupled to the inner circumferential surface of side surface of the housing part, the other end forming a free end, and is formed to be inclined in a downward direction.

9. The collection device that changes width of flow path according to pressure of claim 8,
wherein the collection part further comprises a first extension part extending in a downward direction from the other end forming free end of the first wing part.

10. The collection device that changes width of flow path according to pressure of claim 1,
wherein the collection part comprises a second wing part located on upper side of the inlet part and formed in a shape to restrict flow of fluid ascending from the inlet part,
and the second wing part has one end coupled to the inner circumferential surface of side surface of the housing part, the other end forming free end, and is formed to be inclined in a downward direction.

11. The collection device that changes width of flow path according to pressure of claim 10,
wherein the collection part comprises a second extension part extending in a downward direction from the other end forming free end of the second wing part.

12. The collection device that changes width of flow path according to pressure of claim 10,
wherein the treatment fluid supply part is formed to be inclined in a downward direction along the second wing part,
and comprises a storage part forming a receiving space in which the treatment fluid is stored, and a through-hole, which is a hole penetratingly formed in the storage part so that the treatment fluid stored in the receiving space falls into the internal space.
